(19) United States
(12) Patent Application Publication
(10) Pub. No.: US 2009/0072236 A1
(43) Pub. Date: Mar. 19, 2009

(54) PIXEL STRUCTURE AND MANUFACTURING METHOD THEREOF

(75) Inventor: Han-Chung Lai, Taoyuan Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AU OPTRONICS CORPORATION, Hsinchu (TW)

(21) Appl. No.: 12/327,818

(22) Filed: Dec. 4, 2008

Related U.S. Application Data
(62) Division of application No. 11/160,231, filed on Jun. 15, 2005.

(30) Foreign Application Priority Data
Nov. 5, 2004 (TW) 93133759

(51) Int. Cl. H01L 27/088; H01L 21/8232

(52) U.S. Cl. 257/59; 438/29; 257/E27.06; 257/E21.535

(57) ABSTRACT

A pixel structure and a manufacturing method thereof is provided, the pixel structure including a thin film transistor (TFT), a pixel electrode, a common line, a first dielectric layer and a second dielectric layer. Both of the TFT and the pixel electrode are disposed on the substrate and electrically coupled to each other. The common line is disposed on the substrate under the pixel electrode, while the first dielectric layer is extended from the TFT to under the pixel electrode to cover the common line. The second dielectric layer covers the TFT and is extended from the TFT to under the pixel electrode. The pixel electrode and the common line form a storage capacitor, and the shortest distance between the pixel electrode and the common line is smaller than the sum of the thickness of the first dielectric layer and the thickness of the second dielectric layer in the TFT.

### CROSS-REFERENCE TO RELATED APPLICATION

This application is a divisional application of application Ser. No. 11/160,231, filed on Jun. 15, 2005, which claims the priority benefit of Taiwan application serial no. 93133759, filed on Nov. 5, 2004. The entirety of each of the above-mentioned patent applications is hereby incorporated by reference herein and made a part of this specification.

### BACKGROUND OF THE INVENTION

1. Field of Invention

The present invention relates to a pixel structure and a manufacturing method thereof, more particularly, to a pixel structure of thin film transistor (TFT) array substrate and a manufacturing method thereof.

2. Description of the Prior Art

A thin film transistor liquid crystal display (TFT-LCD) comprises a TFT array substrate, a color filter array substrate and a liquid crystal layer. The TFT array substrate comprises a plurality of thin film transistors (TFTs) with an array configuration and a plurality of pixel electrodes, each of which is configured corresponding to an individual TFT. The TFT is a switch element of a pixel unit. In addition, to control an individual pixel unit, a scan line is employed to select the desired pixel unit (turn on the TFT) and an appropriate operation voltage representing the display information of the pixel unit is applied to pixel electrode through a data line and the TFT. Normally, a part of the above-mentioned pixel electrodes is located above the scan lines or the common lines to form a storage capacitor. In the conventional technology, the storage capacitors can be classified mainly in two types: the metal-insulator-metal (MIM) type and the metal-insulator-ITO (MII) type, wherein ITO is an acronym of indium-tin-oxide. The detail explanation of the two storage capacitor structures will be described as follow.

FIG. 1 is a cross-sectional view of a conventional MIM type storage capacitor. Refer to FIG. 1, in the conventional pixel structure, the MIM type storage capacitor is formed by a scan line (not shown) or a common line 100 and a pixel electrode 120 thereon. The scan line or the common line 100, and the upper electrode 120 of the MIM type storage capacitor are electrically insulated by a gate insulator layer 110. Therefore the storage capacitance Cst of the storage capacitor is related to the thickness of the gate insulator layer 110. The smaller the thickness of the gate insulator layer 110, the higher the storage capacitance Cst. Besides, a pixel electrode 140 is electrically coupled with the upper electrode 120 through a contact window 132 in a passivation layer 130.

FIG. 2 is a cross-sectional view of a conventional MII type storage capacitor. Refer to FIG. 2 in the conventional pixel structure, the MII type storage capacitor is formed by a scan line (not shown) or a common line 200 and a pixel electrode 230 thereon. Differing from the MIM type storage capacitor, the scan line or the common line 200 in the MII type storage capacitor, and a pixel electrode 230 are electrically insulated by a gate insulator layer 210 and a passivation layer 220. Therefore the storage capacitance Cst of the storage capacitor is related to the total thickness of the gate insulator layer 210 and the passivation layer 220. The smaller the total thickness of the gate insulator layer 210 and the passivation layer 220, the higher the storage capacitance Cst.

For the conventional TFT array substrate, in order to increase the storage capacitance Cst without lowering the aperture ratio, it may be required to reduce the thickness of the gate insulator layer 210 or the total thickness of the gate insulator layer 210 and the passivation layer 220. However, the reliability of the TFT devices may be downgraded when the thickness of the gate insulator layer 210 or the total thickness of the gate insulator layer 210 and the passivation layer 220 is reduced.

### SUMMARY OF THE INVENTION

The invention provides a novel pixel structure having a storage capacitor with higher storage capacitance Cst.

As embodied and broadly described herein, the present invention provides a pixel structure controlled by a scan line and a data line on a substrate. The pixel structure comprises a TFT, a pixel electrode, a common line, a first dielectric layer and a second dielectric layer. The TFT is disposed on the substrate, and is controlled by the scan line and the data line. The pixel electrode is disposed on the substrate and electrically coupled to the TFT. The common line is disposed under the pixel electrode on the substrate. The first dielectric layer extends from the TFT to cover the common line under the pixel electrode. The second dielectric layer is located under the pixel electrode and covers the TFT. Noted that a storage capacitor is formed by the pixel electrode and the common line, and the shortest distance between the pixel electrode and the common line is smaller than the total thickness of the first dielectric layer and the second dielectric layer in the TFT.

According to an embodiment of the present invention, the above-mentioned second dielectric layer comprises an indentation over the common line, for example, and the shortest distance between the pixel electrode and the common line is greater than the thickness of the first dielectric layer in the TFT.

According to an embodiment of the present invention, the above-mentioned second dielectric layer comprises, for example, an opening that exposes a portion of the first dielectric layer located over the common line, and the shortest distance between the pixel electrode and the common line is equal to the thickness of the first dielectric layer in the TFT.

According to an embodiment of the present invention, the above-mentioned first dielectric layer and the second dielectric layer comprises, for example, an indentation over the common line, and the shortest distance between the pixel electrode and the common line is smaller than the thickness of the first dielectric layer in the TFT.

According to an embodiment of the present invention, the above-mentioned TFT comprises a gate, a channel layer and a source/drain (S/D). The gate is disposed on the substrate and electrically coupled to the scan line and the gate is covered by the first dielectric layer. In addition, the channel layer is located on the first dielectric layer over the gate, the source/drain is disposed on the channel layer, wherein the source/drain is electrically coupled to the data line and the pixel electrode, respectively, and the source/drain (S/D) is covered by the second dielectric layer.

According to an embodiment of the present invention, the mentioned first dielectric layer and the second dielectric layer comprise a contact window, wherein the pixel electrode is electrically coupled to the S/D via the contact window.

According to an embodiment of the present invention, the above-mentioned TFT further comprises an ohmic contact layer disposed between the channel layer and the S/D.

As embodied and broadly described herein, the present invention provides a method for manufacturing a pixel structure controlled by a scan line and a data line on a substrate. The method comprises following steps. A gate and a common line are formed on the substrate, wherein the gate and the common line connect with the scan line. Then, a first dielectric layer is formed on the substrate to cover the gate and the common line. A channel layer is formed on the first dielectric layer. Thereafter, a source/drain electrically coupled to the data line is formed on the channel layer. A second dielectric layer is formed over the substrate to cover the source/drain. A contact window and an indentation over the common line are formed in the first dielectric layer and the second dielectric layer simultaneously. A pixel electrode is then formed on the substrate such that the pixel electrode is electrically coupled to the source/drain via the contact window, and a storage capacitor is formed by the pixel electrode and the common line. According to an embodiment of the present invention, the indentation may be formed by removing a part of the second dielectric layer over the common line.

According to an embodiment of the present invention, the indentation may be formed by removing completely the second dielectric layer over the common line.

According to an embodiment of the present invention, the indentation may be formed by removing completely the second dielectric layer over the common line and a part of the first dielectric layer over the common line.

According to an embodiment of the present invention, after forming the channel layer, the method further comprises forming a ohmic contact layer on the channel layer.

As embodied and broadly described herein, the present invention provides a pixel structure controlled by a scan line and a data line on the substrate. The pixel structure comprises a TFT, a pixel electrode, a first dielectric layer and a second dielectric layer. The TFT is disposed on the substrate and the TFT is controlled by the scan line and the data line. The pixel electrode is disposed on the substrate and electrically coupled to the TFT, wherein a portion of the pixel electrode is located over to the scan line. The first dielectric layer is extended from the TFT to cover the scan line under the pixel electrode. The second dielectric layer is located under the pixel electrode and covers the TFT. Noted that a storage capacitor is formed by the pixel electrode and the scan line, and the shortest distance between the pixel electrode and the scan line is smaller than the total thickness of first dielectric layer and the second dielectric layer in the TFT.

According to an embodiment of the present invention, the above-mentioned second dielectric layer comprises an indentation, for example, located over the scan line, and the shortest distance between the pixel electrode and the scan line is larger than the thickness of the first dielectric layer in the TFT.

According to an embodiment of the present invention, the above-mentioned second dielectric layer comprises, for example, an opening that exposes a portion of the first dielectric layer located over the scan line, and the shortest distance between the pixel electrode and the scan line is equal to the thickness of the first dielectric layer in the TFT.

According to an embodiment of the present invention, the above-mentioned first dielectric layer and the second dielectric layer comprise, for example, an indentation over the scan line, and the shortest distance between the pixel electrode and the scan line is smaller than the thickness of the first dielectric layer in the TFT.

According to an embodiment of the present invention, the above-mentioned TFT comprises a gate, a channel layer and a source/drain (S/D). The gate is disposed on the substrate and electrically coupled to the scan line, and the gate is covered by the first dielectric layer. The channel layer is located on the first dielectric layer over the gate. The source/drain is disposed on the channel layer, wherein the source/drain is electrically coupled to the data line and the pixel electrode respectively, and covered by the second dielectric layer.

According to an embodiment of the present invention, the above-mentioned first dielectric layer and the second dielectric layer comprise a contact window, wherein the pixel electrode is electrically coupled to the S/D via the contact window.

According to the preferred embodiment of the present invention, the above-mentioned TFT further comprises an ohmic contact layer disposed between the channel layer and the source/drain.

As embodied and broadly described herein, the present invention provides a method for manufacturing a pixel structure controlled by a scan line and a data line on a substrate. The method for manufacturing a pixel structure of the invention comprises following steps. A gate is formed on the substrate, wherein the gate is electrically connected with the scan line. A first dielectric layer is then formed over the substrate to cover the gate and the scan line. A channel layer is then formed on the first dielectric layer. A source/drain is formed on the channel layer, wherein the source/drain is electrically connected with the data line. A second dielectric layer is then formed over the substrate to cover the source/drain. A contact window and an indentation over the scan line are formed in the first dielectric layer and the second dielectric layer simultaneously. A pixel electrode is then formed on the substrate such that the pixel electrode is electrically connects with the source/drain via the contact window, and a storage capacitor is formed by the pixel electrode and the scan line.

According to an embodiment of the invention, the indentation may be formed by removing a part of the second dielectric layer over the scan line.

According to an embodiment of the present invention, the indentation may be formed by removing completely the second dielectric layer over the scan line.

According to an embodiment of the present invention, the indentation may be formed by removing completely the second dielectric layer over the scan line and a part of the first dielectric layer over the scan line.

According to an embodiment of the invention, after forming the channel layer, the method further comprises forming an ohmic contact layer on the channel layer.

As mentioned above, in comparison with prior art, not only the aperture ratio of the pixel structure of the present invention is not affected, but also the storage capacitance of the storage capacitor is higher.

In addition, the manufacturing process of the pixel structure of the present invention is compatible with the currently existed processes; therefore the storage capacitance per unit area can be increased without changing the conventional processes.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

FIG. 1 is a cross-sectional view of a conventional metal-insulator-metal (MIM) type storage capacitor.

FIG. 2 is a cross-sectional view of a conventional metal-insulator-ITO (MII) type storage capacitor.

FIG. 3A is a top view of the pixel structure in accordance with the first embodiment of the present invention.

FIG. 3B is a cross-sectional view along line I-I′ of FIG. 3A.

FIG. 3C is a cross-sectional view along line II-II′ of FIG. 3A.

FIG. 4A-4C are cross-sectional views showing the manufacturing process of the pixel structure in accordance with the first embodiment of the present invention.

FIG. 5A-5C are cross-sectional views showing the manufacturing process of the pixel structure in accordance with the second embodiment of the present invention.

FIG. 6A-6C are cross-sectional views showing the manufacturing process of the pixel structure in accordance with the third embodiment of the present invention.

FIG. 7A is a top view of the pixel structure in accordance with the fourth embodiment of the present invention.

FIG. 7B is a cross-sectional view of the pixel structure in accordance with the fourth embodiment of the present invention.

FIG. 8 is a cross-sectional view of the pixel structure in accordance with the fifth embodiment of the present invention.

FIG. 9 is a cross-sectional view of the pixel structure in accordance with the sixth embodiment of the present invention.

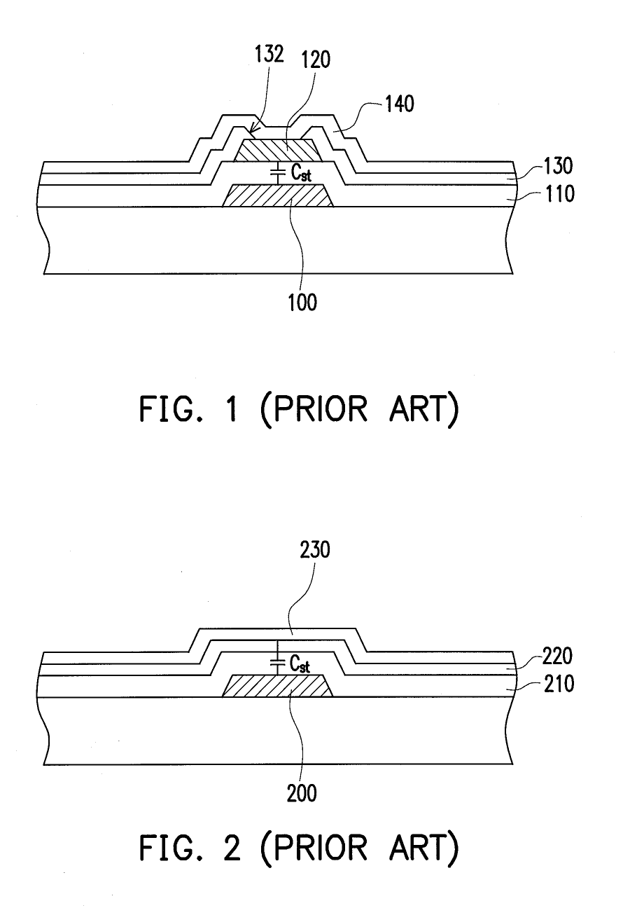

### DESCRIPTION OF EMBODIMENTS

To further express the taken technical means for achieving the predetermined goals of the invention and the efficacy, the detailed description of the pixel structures and the manufacturing methods thereof proposed by the present invention are given hereinafter with the preferred embodiments and accompanying drawings.

### The First Embodiment

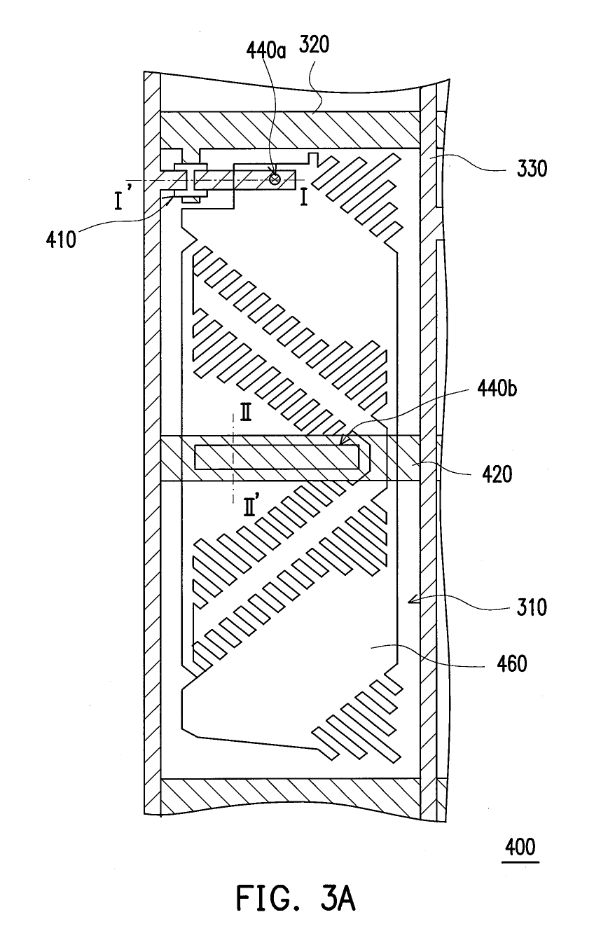

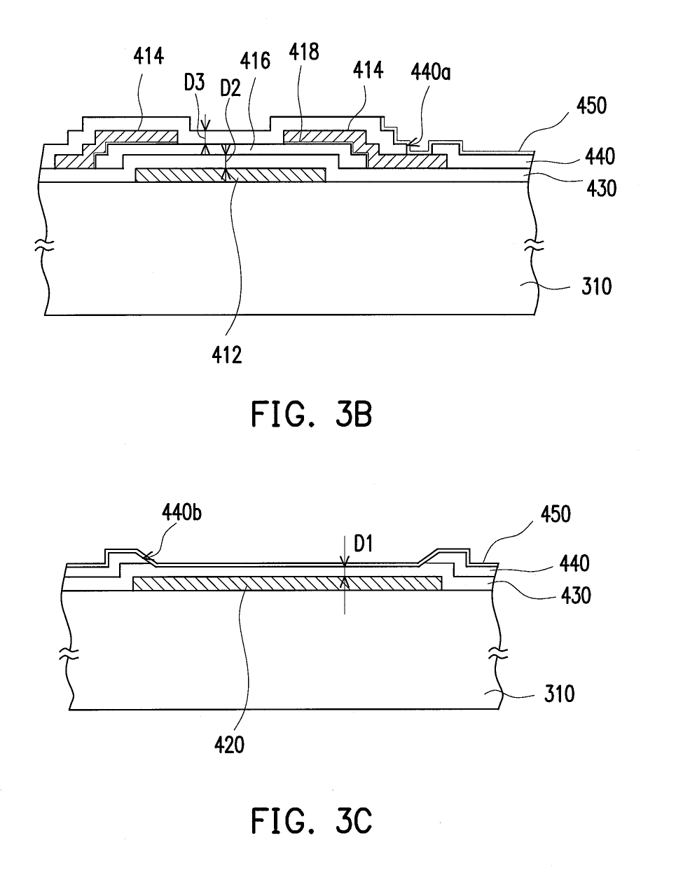

FIG. 3A is the top view of the pixel structure in accordance with the first embodiment of the present invention, FIG. 3B is a cross-sectional view along line I-I′ of FIG. 3A, and FIG. 3C is a cross-sectional view along line II-II′ of FIG. 3A. As illustrated in FIG. 3A, the pixel structure 400 of the present invention is controlled by a scan line 320 and a data line 330 located on substrate 310. The substrate 300 can be made of, for example, glass, plastic or other materials.

Referring to FIG. 3A-3C, the pixel structure 400 comprises a TFT 410, a common line 420, a first dielectric layer 430, a second dielectric layer 440 and a pixel electrode 450. The TFT 410 is disposed on substrate 310 and is controlled by the scan line 320 and data line 330. In addition, the TFT 410 comprises a gate 412, a source/drain 414 and a channel layer 416. The gate 412 and the common line 420 are disposed on the substrate 310, and the gate 412 and the scan line 320 are electrically coupled to each other. Furthermore, the gate 412 and the common line 420 are made of, for example, chromium, aluminum or the other conductive material.

As illustrated in FIG. 3C, first dielectric layer 430 covers the gate 412 and the common line 420, and the first dielectric layer 430 is made of, for example, silicon oxide, silicon nitride or the other dielectric material. Besides, a channel layer 416 is disposed on the first dielectric layer 430 over the gate 412, and the source/drain 414 is disposed on channel layer 416, wherein one of the source/drain 414 is electrically coupled to the data line 330. The above-described source/drain 414 is made of, for example, chromium, aluminum or the other conductive materials.

In detail, to enhance the performance of the devices, the TFT 410 further comprises an ohmic contact layer 418 located between channel layer 416 and source/drain 414. Besides, the channel layer 416 is made of, for example, amorphous silicon, and the ohmic contact layer is made of, for example, n-type doped amorphous silicon.

The source/drain 414 is covered by a second dielectric layer 440, and the second dielectric layer 440 is made of, for example, silicon oxide, silicon nitride or the other dielectric material. Besides, a pixel electrode 450 is disposed on substrate 310, and the pixel electrode 450 is electrically coupled to the source/drain 414. The pixel electrode 450 is made of, for example, indium tin oxide (ITO), indium zinc oxide (IZO) or other conductive materials. Specifically, the first dielectric layer 430 and second dielectric layer 440 comprise a contact window 440a therein, and pixel electrode 450 is electrically coupled to source/drain 414 via contact window 440a. It should be noted that the pixel electrode 45 may comprise jagged or non-jagged slits to meet the requirements of MVA technology. However, the present invention is not limited to the type of the pixel electrode 450.

As illustrated in FIG. 3C, an MIM type storage capacitor is formed by the foregoing pixel electrode 450 and the common line 420. It should be noted that the shortest distance D1 between the pixel electrode 450 and the common line 420 is smaller than the sum of the thickness D2 of first dielectric layer 430 and the thickness D3 of second dielectric layer 440 in the TFT 410.

An indentation 440b is formed in the first dielectric layer 430 and the second dielectric layer 440. The indentation 440b is located over the common line 420; therefore the shortest distance D1 between the pixel electrode 450 and the common line 420 is smaller than the sum of the thickness D2 of the first dielectric layer 430 over gate 412 and the thickness D3 of second dielectric layer 440.

In comparison with the prior art as illustrated in FIG. 2, the distance between the pixel electrode 450 and the common line 420 as described in the present invention is shorter; thus, the pixel structure 400 has a storage capacitor with higher storage capacitance. Besides, this higher storage capacitance of the storage capacitor is obtained without lowering the aperture ratio. The relevant manufacturing process of the pixel structure 400 will be described in following paragraphs.

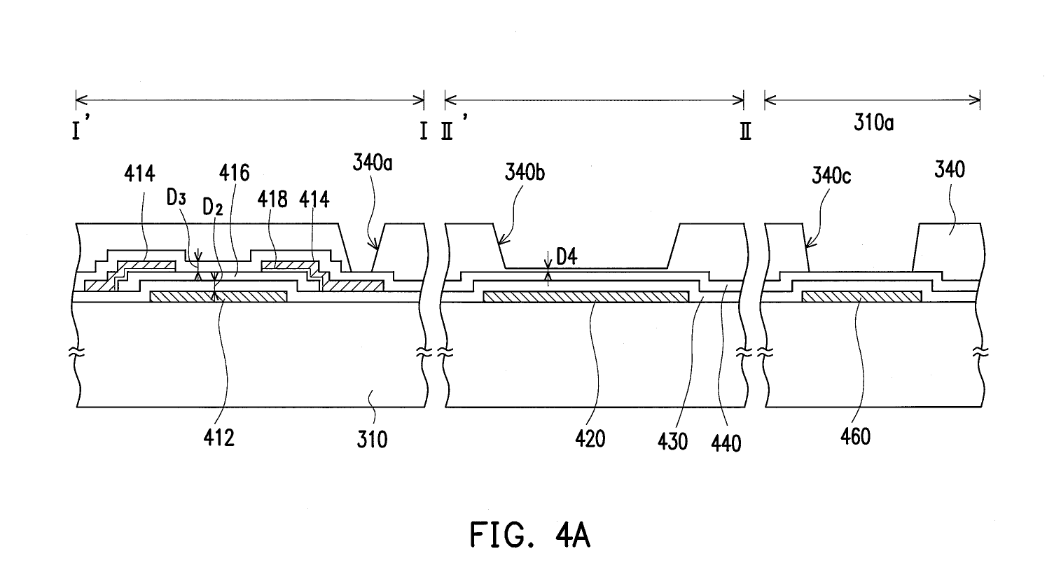

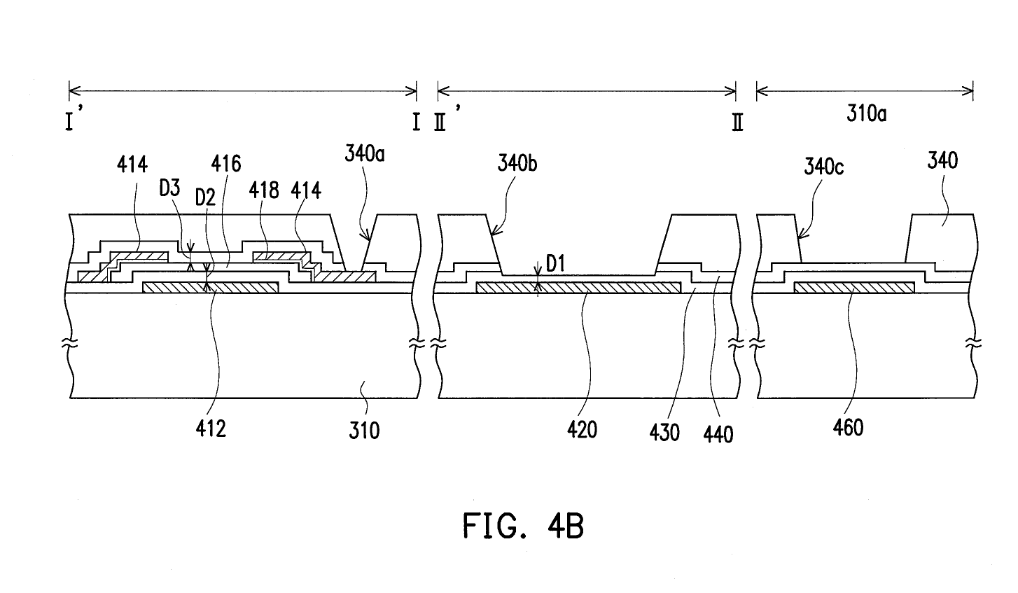

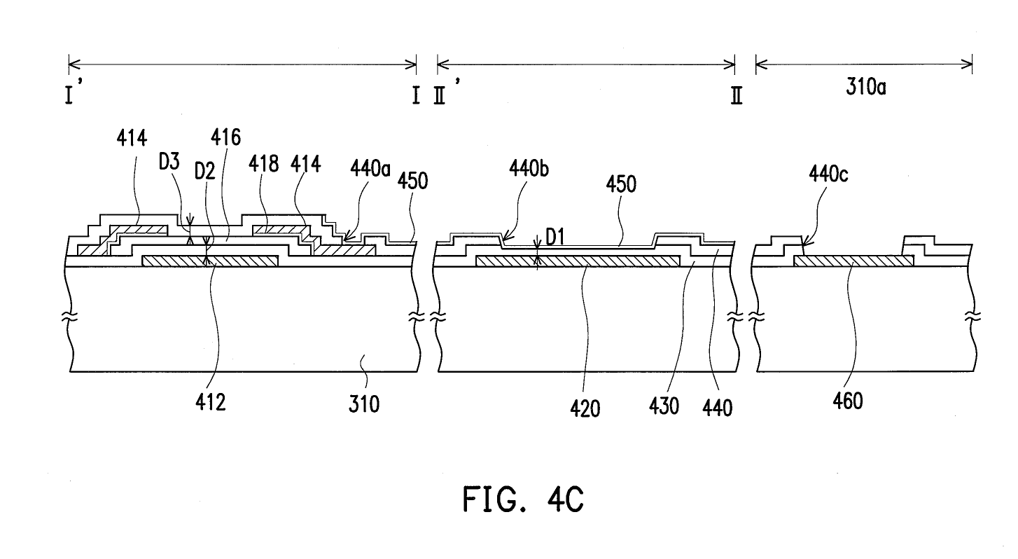

FIG. 4A-4C are cross-sectional views showing the manufacturing process of the pixel structure in accordance with the first embodiment of the present invention. Referring to FIG. 4A, the manufacturing process of the pixel structure 400 comprises following steps. First, the gate 412 and the common line 420 are formed on substrate 310, and a pad 460 is formed on a peripheral area 310a of the substrate 310. The gate 412, the scan line 420 and the pad 460 are simultaneously formed, for example, and the scan line 420 is electrically coupled to both of the pad 460 and the gate 412. The pad 460 is suitable for electrically connecting with a driver IC. Besides, the scan line 320, the gate 412, the common line 420 and the pad 460 is, for example, manufactured by following steps. First, a sputtering or other physical vapor deposition (PVD) process is performed to form a conductive layer (not shown in the figures) on substrate 310, and then the conductive layer may be patterned to form the scan line 320, the gate 412, the common line 420 and the pad 460.

Next, a first dielectric layer 430, which covers the scan line 320, the gate 412, the common line 420 and the pad 460, is formed on the substrate 310. The process to form the first dielectric layer 430 comprises but not limited to plasma enhanced CVD (PECVD) or other chemical vapor deposition (CVD) process.

Furthermore, a channel layer 416 is formed on the first dielectric layer 430, and an ohmic contact layer 418 is formed on channel layer 416. Thereafter, the source/drain 414 is formed on the ohmic contact layer 418, wherein the source/drain 414 is electrically coupled to the data line 330. Preferably, the source/drain 414 and the data line 330 are manufactured simultaneously, for example. The source/drain 414 and the data line 330 is, for example, manufactured by following steps. First, a conductive layer (not shown in the figures) is formed on substrate 310 by sputtering or other physical vapor deposition (PVD) process, and then the conductive layer is patterned to form the source/drain 414 and the data line 330.

The second dielectric layer 440 is formed over the substrate 310 to cover the source/drain 414, the data line 330 and the pad 460. The process to form the second dielectric layer 440 can be, for example, plasma enhanced CVD (PECVD) or other chemical vapor deposition (CVD) processes.

A patterned photoresist layer 340 is formed on the substrate 310, wherein the photoresist layer 340 has an indentation 340b, an opening 340a and an opening 340c. In the present embodiment, the indentation 340b is located above the common line 420, and the thickness of the photoresist layer 340 over the common line 420 is D4. In addition, the opening 340a partially exposes the surface of the second dielectric layer 440 over the source/drain 414, and the opening 340c partially exposes the surface of the second dielectric layer 440 over the pad 460. The process to form the patterned photoresist layer 340 comprises, for example, entirely forming a photoresist layer on the substrate 310, and then exposing and developing the photoresist layer to form the patterned photoresist layer 340. It should noted that the patterned photoresist layer 340 over the common line 420 has a thickness D4, which is smaller than the thickness of photoresist layer located at other area.

Referring to FIGS. 4B and 4C, an etching process is performed on the first dielectric layer 430 and the second dielectric layer 440 until a contact window 440a and a contact window 440c are formed in the first dielectric layer 430 and the second dielectric layer 440. A part of the surface of the source/drain and a part of the pad 460 are exposed respectively by the contact window 440a and the contact window 440c, wherein the pad 460 serves as the etch stop layer for the etching process. At the same time, the second dielectric layer 440 located over the common line 420 is removed completely, and only a part of the first dielectric layer 430 is removed. Accordingly, an indentation 440b is formed in first dielectric layer 430 and second dielectric layer 440. In other words, the first dielectric layer 430 with only a partial thickness remains over the common line 420.

Referring to FIG. 4C, after removing the patterned photoresist layer 340, a pixel electrode 450 is formed over the substrate 310, wherein the pixel electrode 450 is electrically coupled to the source/drain 414 via the contact window 440a, and a storage capacitor is formed by the pixel electrode 450 and the common line 420. Noted that the manufacturing process of the pixel structure of the present invention is compatible with the currently existed processes; therefore the storage capacitance per unit area can be increased without additional process. As described above, the shortest distance D1 between the pixel electrode 450 and the common line 420 is determined by the thickness D4 of the patterned photoresist layer 340 over common line 420. In other words, the pixel structures having storage capacitor with higher storage capacitances can be made by reducing the thickness of the patterned photoresist layer 340 over the common line 420. The relevant design for that will be described in detail in following paragraphs.

### 2. The Second Embodiment

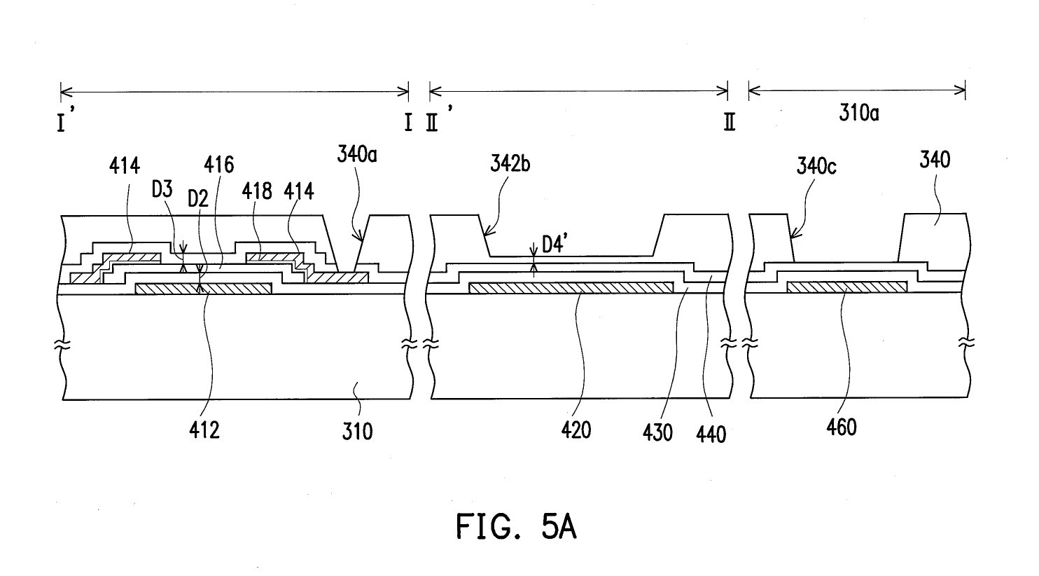

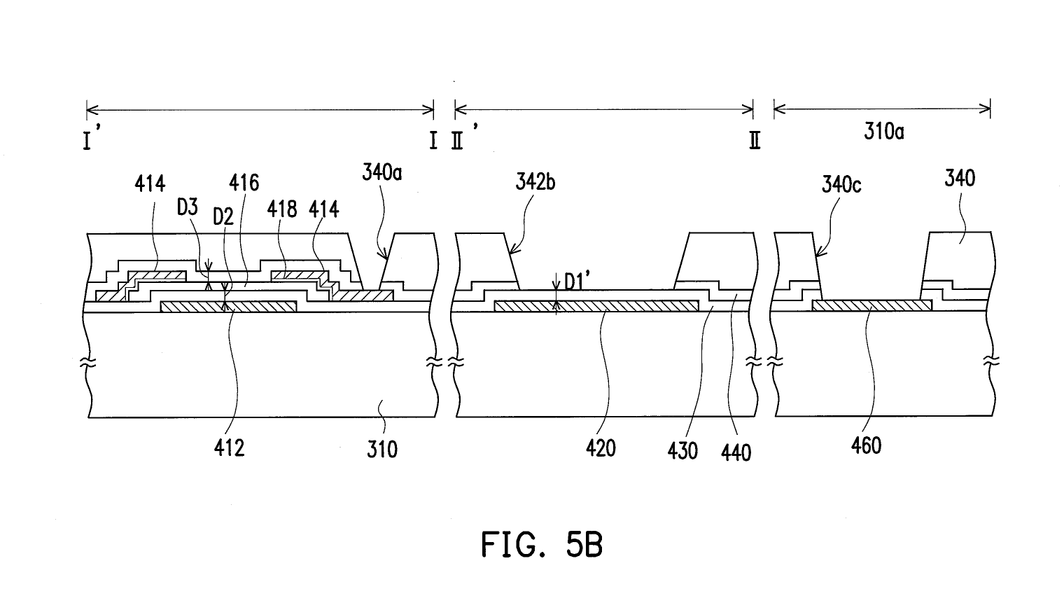

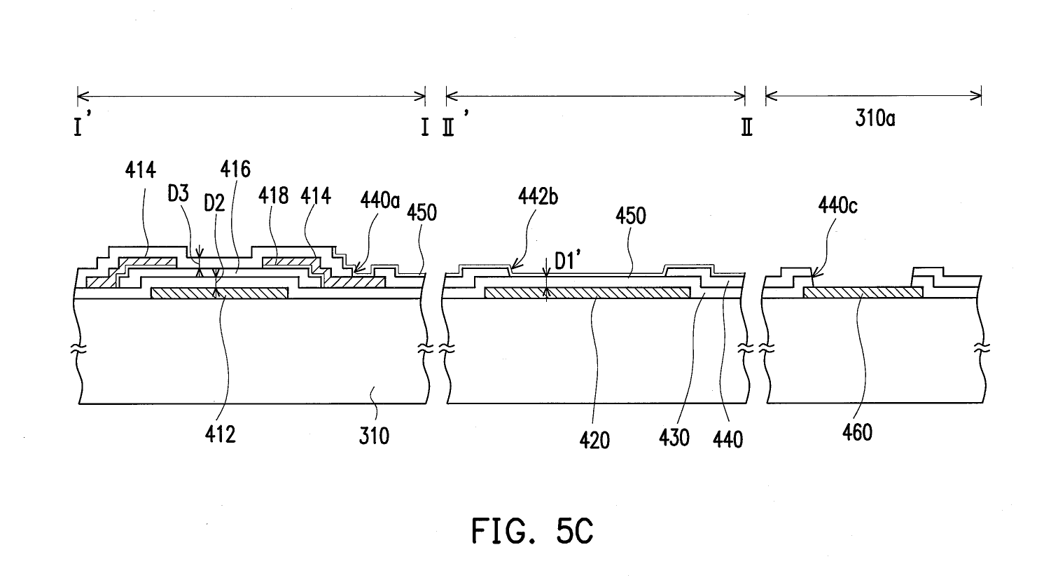

FIG. 5A-5C are cross-sectional views showing the manufacturing process of the pixel structure in accordance with the second embodiment of the present invention. The second embodiment is similar to the first embodiment; thus, only the differences between the two embodiments are explained in detail.

Referring to FIG. 5A, after forming the gate 412, the common line 420, the pad 460, the first dielectric layer 430, the semiconductor layer 416, the source/drain 414 and the second dielectric layer 440, the patterned photoresist layer 340 over the substrate 310 is formed. An indentation 342b is formed in the patterned photoresist layer 340 over the common line 420; therefore, the actual residual thickness of the patterned photoresist layer 340 over common line 420 is D4′. Then, an etching is performed to ash the patterned photoresist layer 340 and remove a portion of the second dielectric layer 440 until the pad 460 is exposed. At this time, the second dielectric layer 440 has an opening 442b, which exposes partially the surface of the first dielectric layer 430 over the common line 420.

After removing the patterned photoresist layer 340, a pixel electrode 450 is formed on the second dielectric layer 440, wherein the shortest distance D1′ between the pixel electrode 450 and the common line 420 is smaller than the sum of the thickness D2 of first dielectric layer 430 and the thickness D3 of second dielectric layer 440. In comparison with the prior art, the pixel structure formed by the manufacturing method discussed in the second embodiment has a storage capacitor with higher storage capacitance.

### 3. The Third Embodiment

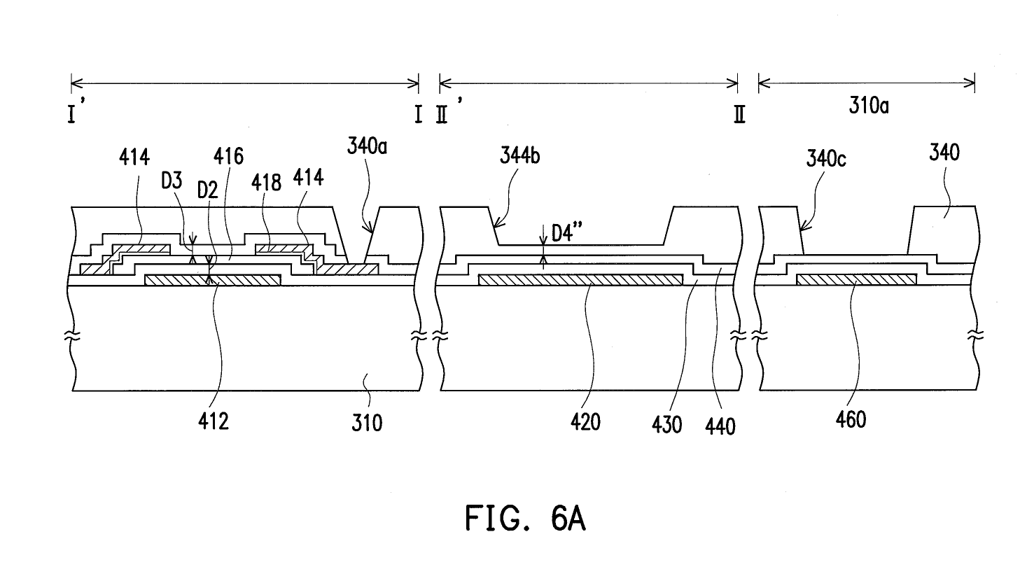

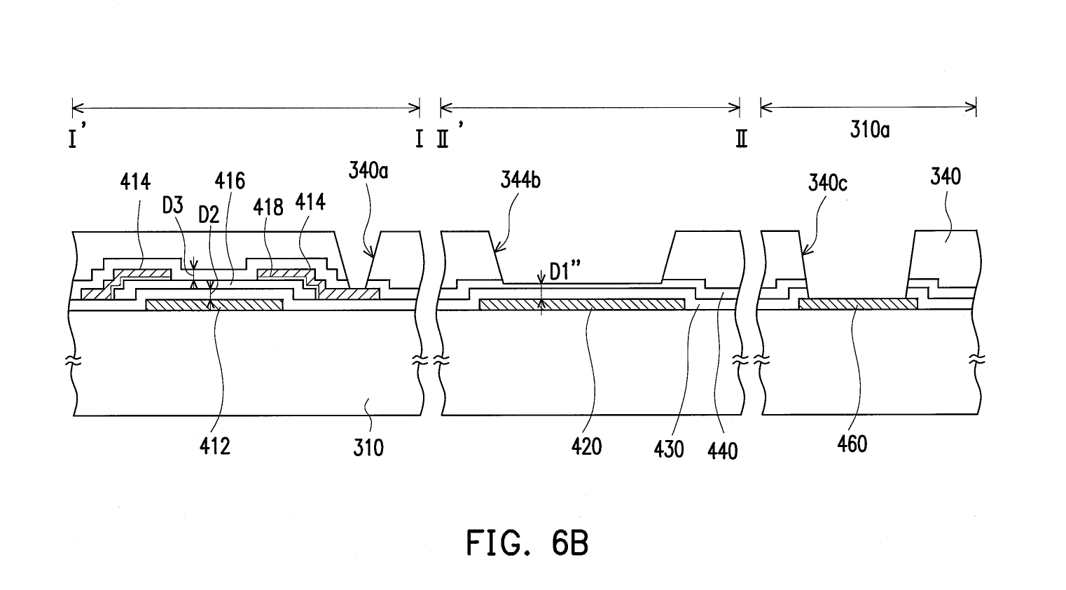

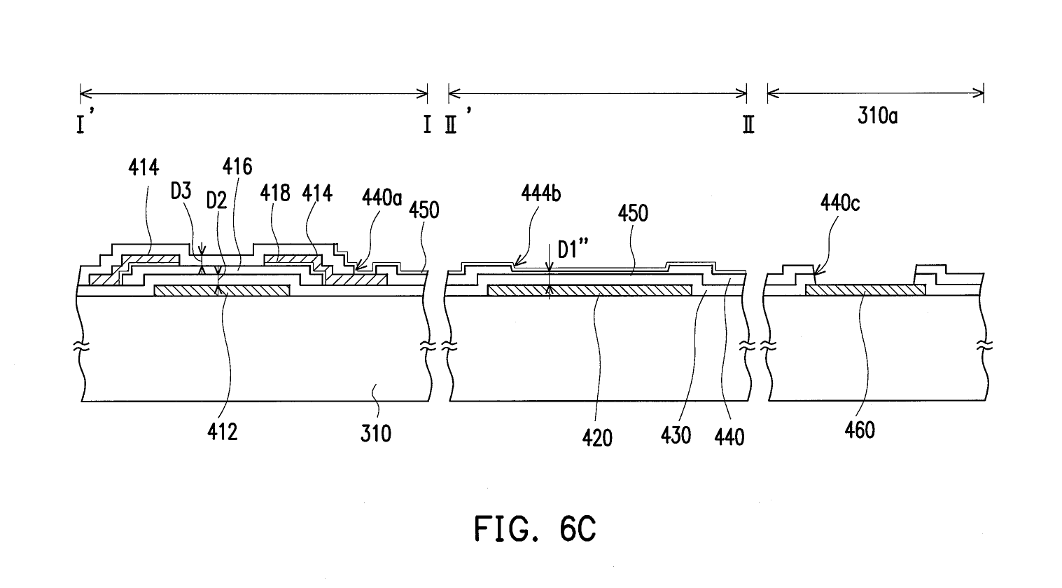

FIG. 6A-6C are cross-sectional views showing the manufacturing process of the pixel structure in accordance with the third embodiment of the present invention. The present embodiment is similar to the first embodiment, thus only the differences between two embodiments are explained in detail.

Referring to FIG. 6A, similar to the first embodiment, after forming the gate 412, the common line 420, the pad 460, the first dielectric layer 430, the semiconductor layer 416, the source/drain 414 and the second dielectric layer 440, a patterned photoresist layer 340 on substrate 310 is formed. The indentation 344b is formed in the patterned photoresist layer 340 over the common line 420; therefore, the actual residual thickness of the patterned photoresist layer 340 over the common line 420 is D4″.

Then, an etching process is performed to ash the patterned photoresist layer 340 and remove a portion of the second dielectric layer 440 until the pad 460 is exposed. At this time, an indentation 444b is formed in the second dielectric layer 440, and the indentation 444b is located over the common line 420. A pixel electrode 450 is then formed on the second dielectric layer 440 after removing the patterned photoresist layer 340. The shortest distance D1″ between pixel electrode 450 and the common line 420 is smaller than the sum of the thickness D2 of first dielectric layer 430 and the thickness D3 of second dielectric layer 440.

As described above, the MII type storage capacitors of the first, the second and the third embodiment are all formed on the common line. However, the MII type storage capacitors can be formed on the scan line as discussed in the following paragraphs.

### 4. The Fourth Embodiment

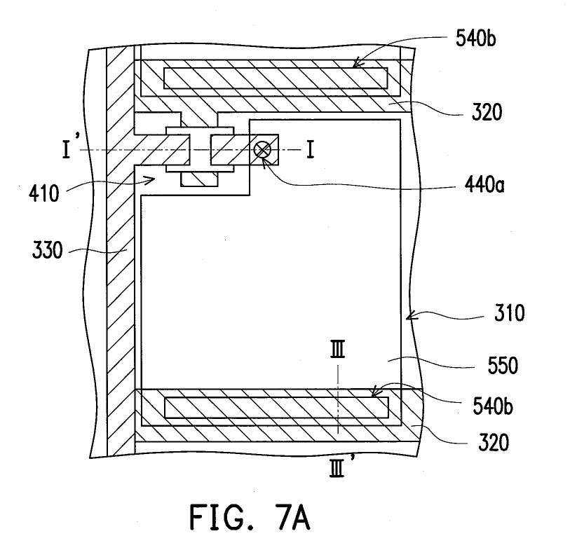

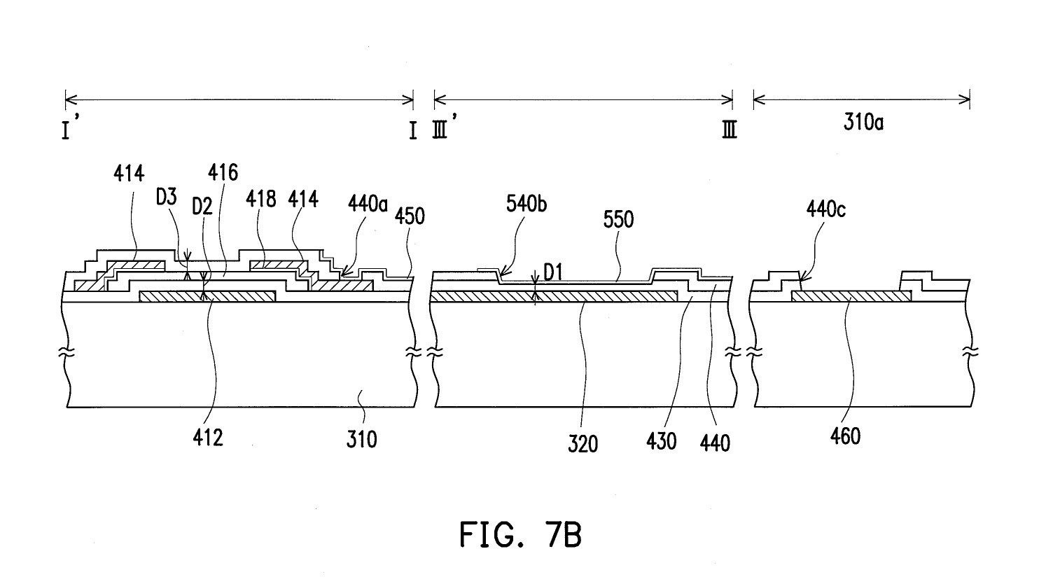

FIG. 7A is a top view of the pixel structure in accordance with the fourth embodiment of the present invention, and FIG. 7B is a cross-sectional view of the pixel structure in accordance with the fourth embodiment of the present invention. The fourth embodiment is similar to the first preferred embodiment; thus only the differences between two embodiments are explained in detail.

Referring to FIGS. 7A and 7B, the pixel electrode 550 is extended over scan line 320, wherein a storage capacitor is formed by the pixel electrode 550 and the scan line 320. Furthermore, the shortest distance between the pixel electrode 550 and the scan line 320 is smaller than the sum of the thickness of the first dielectric layer 430 and the thickness of the second dielectric layer 440. The second dielectric layer 440 has, for example, an indentation 540b located over scan line 320, and the shortest distance D1 between pixel electrode 550 and scan line 320 is smaller than the thickness D2 of the first dielectric layer 430 in the TFT. Besides, the process to form the indentation 540b is similar to the process to form the indentation 440b in the first embodiment.

### 5. The Fifth Embodiment

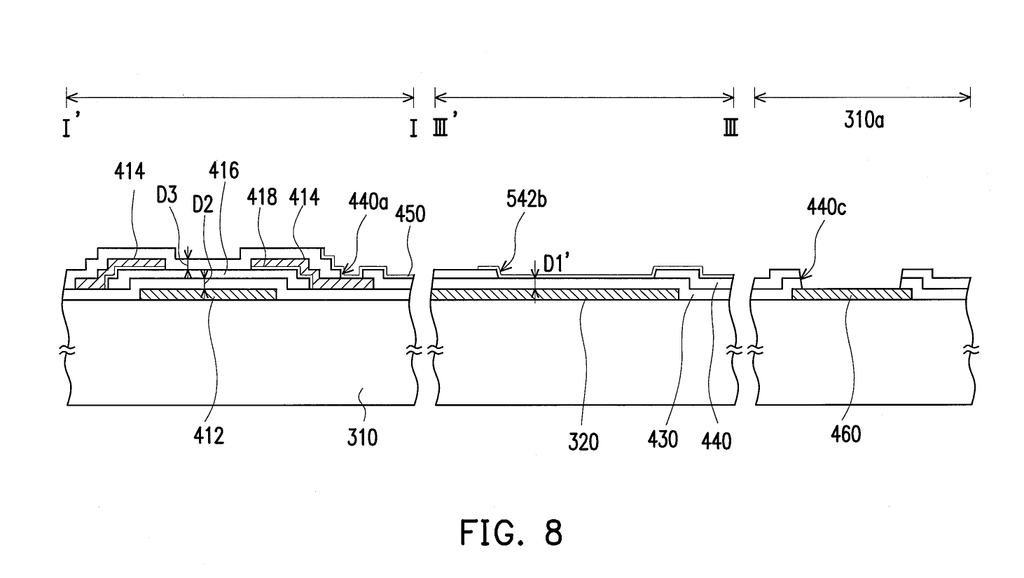

FIG. 8 is a cross-sectional view of the pixel structure in accordance with the fifth d embodiment. The fifth embodiment is similar to the second embodiment; thus only the differences between the two embodiments are explained in detail.

Referring to FIG. 8, the second dielectric layer 440 has an opening 542b therein, and the opening 524b is located over the scan line 320. The opening 542b exposes a part of the scan line 320. In addition, an etching process is performed to form the opening 542b in the second dielectric layer 440 until the pad 460 is exposed. Meanwhile, the shortest distance D1′ between the pixel electrode 550 and the scan line 320 is equal to the thickness D1 of the first dielectric layer 430 in the TFT. Besides, the process of forming the opening 542b is similar to the process in forming the opening 442b in the second embodiment.

### 6. The Sixth Embodiment

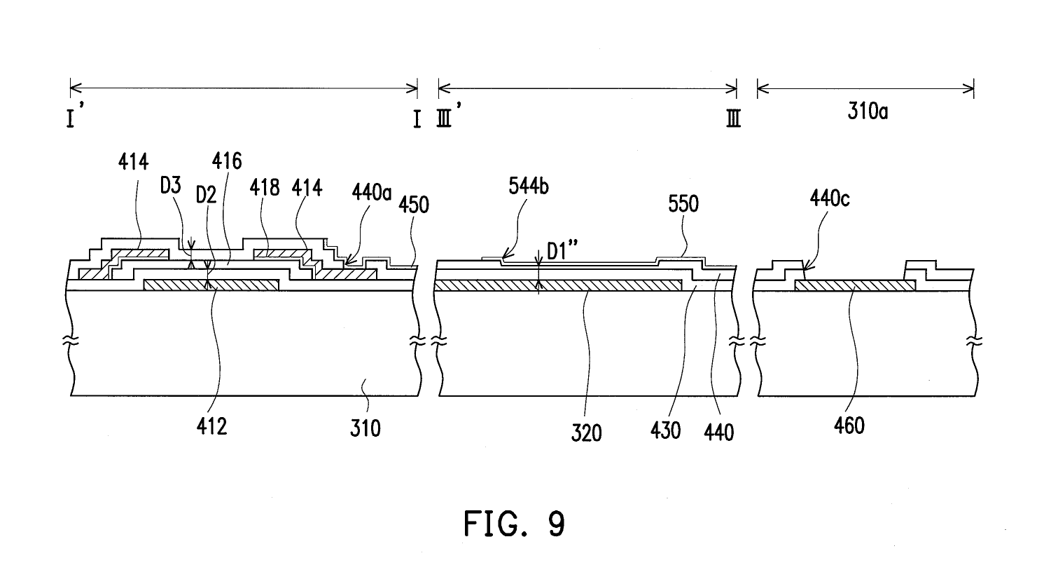

FIG. 9 is a cross-sectional view of the pixel structure in accordance with the sixth embodiment. The sixth embodiment is similar to the third embodiment, except that the second dielectric layer 440 has an indentation 544b located over the scan line 320. Noted that the shortest distance D1″ between the pixel electrode 550 and the scan line 320 is larger than the thickness D1 of first dielectric layer 430 in the TFT. Besides, the process for forming the indentation 544b is similar to the process for forming the indentation 442b in the third embodiment.

To sum up, the pixel structure of the present invention and the manufacturing method thereof have at least the following advantages in comparison with the prior art:

The pixel structure of the present invention has a storage capacitor with higher storage capacitance.

The pixel structure of the present invention can increase the storage capacitance of the storage capacitor without lowering the aperture ratio.

The manufacturing process of the present invention is compatible with the currently existed processes; therefore, the storage capacitance per unit area can be increased without significantly modifying the conventional processes.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A pixel structure formed on a substrate having a scan line and a data line arranged thereon, comprising:
a thin film transistor (TFT) disposed on the substrate and coupled to the scan line and the data line;
a pixel electrode disposed on the substrate and electrically coupled to the TFT;
a common line disposed under the pixel electrode on the substrate;
a first dielectric layer extended from the TFT so as to cover the common line under the pixel electrode; and
a second dielectric layer disposed under the pixel electrode and covering the TFT, wherein the shortest distance between the pixel electrode and the common line is shorter than the total thickness of the first dielectric layer and the second dielectric layer in the TFT, and an indentation is formed in the first dielectric layer and the second dielectric layer over the common line such that the shortest distance between the pixel electrode and the common line is shorter than the thickness of the first dielectric layer in the TFT.

2. The pixel structure according to claim 1, wherein the TFT comprises:
a gate disposed on the substrate and electrically coupled to the scan line, the gate being covered by the first dielectric layer;
a channel layer disposed on the first dielectric layer over the gate; and
a source/drain disposed on the channel layer and electrically coupled to the data line and the pixel electrode, respectively, and covered by the second dielectric layer.

3. The pixel structure according to claim 2, further comprising a contact window formed in the first dielectric layer and the second dielectric layer so that the pixel electrode is electrically coupled to the source/drain.

4. The pixel structure according to claim 2, wherein the TFT further comprises an ohmic contact layer disposed between the channel layer and the source/drain.

5. A method for manufacturing a pixel structure formed on a substrate having a scan line and a data line arranged thereon, comprising:
forming a gate and a common line coupled to the scan line on the substrate;
forming a first dielectric layer on the substrate so as to cover the gate and the common line;
forming a channel layer on the first dielectric layer;
forming a source/drain on the channel layer, wherein the source/drain is coupled to the data line;
forming a second dielectric layer on the substrate so as to cover the source/drain;
forming a contact window over the source/drain and an indentation over the common line in the first dielectric layer and the second dielectric layer, wherein the indentation is formed by removing completely the second dielectric layer over the common line and a part of the first dielectric layer over the common line; and
forming a pixel electrode on the substrate, wherein the pixel electrode is coupled to the source/drain over the common line.

6. The method according to claim 5, further comprising forming an ohmic contact layer on the channel layer.

7. A pixel structure formed on a substrate having a scan line and a data line arranged thereon, comprising:
a thin film transistor (TFT) disposed on the substrate and coupled to the scan line and the data line;
a pixel electrode disposed on the substrate and electrically coupled to the TFT, wherein a portion of the pixel electrode is located over the scan line;
a first dielectric layer extended from the TFT so as to cover the scan line under the pixel electrode; and
a second dielectric layer disposed under the pixel electrode and covering the TFT, wherein the shortest distance between the pixel electrode and the scan line is shorter than the total thickness of the first dielectric layer and the second dielectric layer in the TFT, and an indentation is formed in the first dielectric layer and the second dielectric layer over the scan line such that the shortest distance between the pixel electrode and the scan line is shorter than the thickness of the first dielectric layer in the TFT.

8. The pixel structure according to claim 7, wherein the TFT comprises:
a gate disposed on the substrate and electrically coupled to the scan line and covered by the first dielectric layer;
a channel layer disposed on the first dielectric layer over the gate; and
a source/drain (S/D) disposed on the channel layer, wherein the source/drain is electrically coupled to the data line and the pixel electrode, respectively, and covered by the second dielectric layer.

9. The pixel structure according to claim 8, further comprising a contact window formed in the first dielectric layer and the second dielectric layer, whereby the pixel electrode is electrically coupled to the source/drain via the contact window.

10. The pixel structure according to claim 8, wherein the TFT further comprises an ohmic contact layer disposed between the channel layer and the source/drain.

11. A method for manufacturing a pixel structure formed on a substrate having a scan line and a data line arranged thereon, comprising:
forming a gate coupled to the scan line on the substrate;
forming a first dielectric layer on the substrate to cover the gate and the scan line;
forming a channel layer on the first dielectric layer;
forming a source/drain on the channel layer, wherein the source/drain is coupled to the data line;
forming a second dielectric layer on the substrate to cover the source/drain;
forming a contact window over the source/drain and an indentation over the scan line in the first dielectric layer and the second dielectric layer simultaneously, wherein the indentation is formed by removing completely the second dielectric layer over the scan line and a part of the first dielectric layer over the scan line; and
forming a pixel electrode on the substrate, wherein the pixel electrode is electrically coupled to the source/drain via the contact window.

12. The method of claim 11, further comprising forming an ohmic contact layer on the channel layer.
